(19) United States
(12) Patent Application Publication
(10) Pub. No.: US 2024/0089637 A1
(43) Pub. Date: Mar. 14, 2024

(54) IMAGING APPARATUS

(71) Applicant: SONY SEMICONDUCTOR SOLUTIONS CORPORATION, KANAGAWA (JP)

(72) Inventor: MASANAO YOKOYAMA, KANAGAWA (JP)

(21) Appl. No.: 18/261,575

(22) PCT Filed: Dec. 23, 2021
(86) PCT No.: PCT/JP2021/047979

§ 371 Date: Jul. 14, 2023

(30) Foreign Application Priority Data
Jan. 25, 2021 (JP) 2021-009618

(51) Int. Cl. H04N 25/78; H04N 23/667; H04N 25/79

(52) U.S. Cl. CPC H04N 25/78; H04N 23/667; H04N 25/79; H01L 27/14634

(57) ABSTRACT

An imaging apparatus of the present disclosure includes: a pixel array including a plurality of light-receiving pixels including a first light-receiving pixel, a second light-receiving pixel, and a third light-receiving pixel, each generating a pixel signal in response to a received light amount, in which the first light-receiving pixel, the second light-receiving pixel, and the third light-receiving pixel are arranged in this order in a first direction; and a readout section including a first AD converter that performs AD conversion on the basis of each of the pixel signal generated by the first light-receiving pixel and the pixel signal generated by the third light-receiving pixel, and a second AD converter that performs AD conversion on the basis of the pixel signal generated by the second light-receiving pixel.

### TECHNICAL FIELD

The present disclosure relates to an imaging apparatus that captures an image of a subject.

### BACKGROUND ART

Some imaging apparatuses include, for example, a first semiconductor substrate provided with a plurality of light-receiving pixels and a second semiconductor substrate provided with a plurality of AD converters. For example, PTL 1 discloses a technique in which each of the plurality of AD converters performs AD conversion on the basis of light reception results of the light-receiving pixels provided in a region corresponding to a region in which the AD converters are arranged.

### CITATION LIST

### Patent Literature

PTL 1: Japanese Unexamined Patent Application Publication No. 2018-98524

### SUMMARY OF THE INVENTION

Incidentally, an imaging apparatus is desired to have high image quality, and is expected to have further improved image quality.

It is desirable to provide an imaging apparatus that makes it possible to enhance image quality.

An imaging apparatus according to an embodiment of the present disclosure includes a pixel array and a readout section. The pixel array includes a plurality of light-receiving pixels including a first light-receiving pixel, a second light-receiving pixel, and a third light-receiving pixel, each generating a pixel signal. The first light-receiving pixel, the second light-receiving pixel, and the third light-receiving pixel are arranged in this order in a first direction. The readout section includes a first AD converter that performs AD conversion on the basis of each of the pixel signal generated by the first light-receiving pixel and the pixel signal generated by the third light-receiving pixel, and a second AD converter that performs AD conversion on the basis of the pixel signal generated by the second light-receiving pixel.

In the imaging apparatus according to an embodiment of the present disclosure, the plurality of light-receiving pixels including the first light-receiving pixel, the second light-receiving pixel, and the third light-receiving pixel is provided in the pixel array. In each of the plurality of light-receiving pixels, a pixel signal in response to a received light amount is generated. The first light-receiving pixel, the second light-receiving pixel, and the third light-receiving pixel are arranged in this order in the first direction. In the readout section, the first AD converter performs AD conversion on the basis of the pixel signal generated by the first light-receiving pixel and the pixel signal generated by the third light-receiving pixel, and the second AD converter performs AD conversion on the basis of the pixel signal generated by the second light-receiving pixel.

### BRIEF DESCRIPTION OF THE DRAWINGS

FIG. 1 is a block diagram illustrating a configuration example of an imaging apparatus according to an embodiment of the present disclosure.

FIG. 2 is an explanatory diagram illustrating a configuration example of a pixel array illustrated in FIG. 1.

FIG. 3A is an explanatory diagram illustrating an operation example of the pixel array illustrated in FIG. 2 in a first operation mode.

FIG. 3B is an explanatory diagram illustrating an operation example of the pixel array illustrated in FIG. 2 in a second operation mode.

FIG. 4 is a circuit diagram illustrating a configuration example of a light-receiving pixel and a readout circuit illustrated in FIG. 2.

FIG. 5 is an explanatory diagram illustrating an example of implementation of the imaging apparatus illustrated in FIG. 1.

FIG. 6 is another explanatory diagram illustrating an example of the implementation of the imaging apparatus illustrated in FIG. 1.

FIG. 7 is an explanatory diagram illustrating an example of arrangement of the readout circuit illustrated in FIG. 4.

FIG. 8 is a timing waveform diagram illustrating an operation example of the imaging apparatus illustrated in FIG. 1.

FIG. 9 is an explanatory diagram illustrating an operation example of the imaging apparatus illustrated in FIG. 1 in the first operation mode.

FIG. 10 is another explanatory diagram illustrating an operation example of the imaging apparatus illustrated in FIG. 1 in the first operation mode.

FIG. 11 is an explanatory diagram illustrating an operation example of the imaging apparatus illustrated in FIG. 1 in the second operation mode.

FIG. 12 is another explanatory diagram illustrating an operation example of the imaging apparatus illustrated in FIG. 1 in the second operation mode.

FIG. 13 is an explanatory diagram illustrating an operation example of the imaging apparatus illustrated in FIG. 1.

FIG. 14 is another explanatory diagram illustrating an operation example of the imaging apparatus illustrated in FIG. 1 in the first operation mode.

FIG. 15 is another explanatory diagram illustrating an operation example of the imaging apparatus illustrated in FIG. 1 in the second operation mode.

FIG. 16 is another explanatory diagram illustrating an operation example of the imaging apparatus illustrated in FIG. 1 in the second operation mode.

FIG. 17 is an explanatory diagram illustrating an example of arrangement of light-receiving pixels to be read by a certain readout circuit in the imaging apparatus illustrated in FIG. 1.

FIG. 18 is an explanatory diagram illustrating another example of the arrangement of light-receiving pixels to be read by a certain readout circuit in the imaging apparatus illustrated in FIG. 1.

FIG. 19 is an explanatory diagram illustrating an example of application of the imaging apparatus illustrated in FIG. 1.

FIG. 20 is an explanatory diagram illustrating a usage example of the imaging apparatus.

FIG. 21 is a block diagram depicting an example of schematic configuration of a vehicle control system.

FIG. 22 is a diagram of assistance in explaining an example of installation positions of an outside-vehicle information detecting section and an imaging section.

### MODES FOR CARRYING OUT THE INVENTION

Hereinafter, detailed description is given of an embodiment of the present disclosure with reference to the drawings. It is to be noted that the description is given in the following order.
1. Embodiment
2. Usage Example of Imaging Apparatus
3. Example of Practical Application to Mobile Body

### 1. Embodiment

### Configuration Example

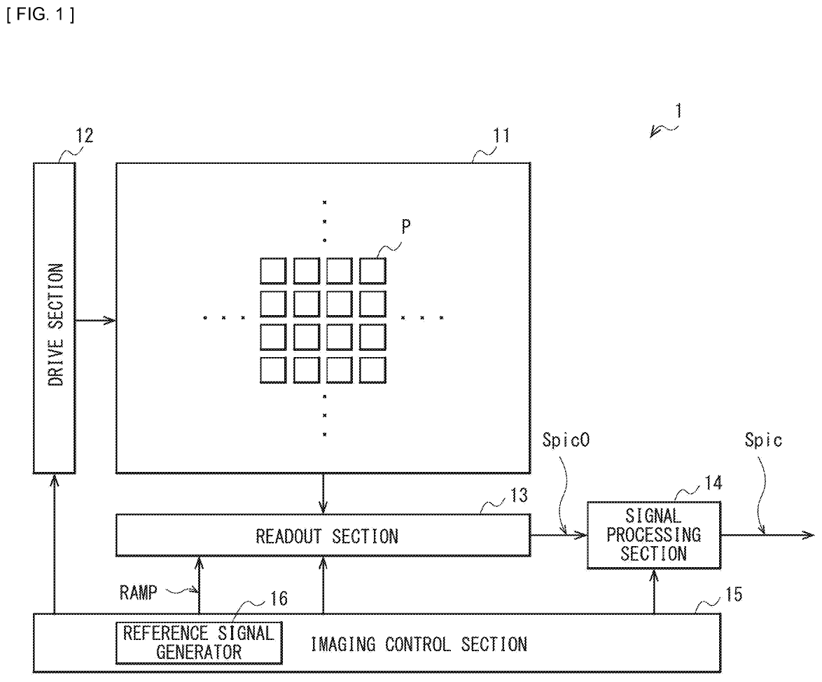

FIG. 1 illustrates a configuration example of an imaging apparatus (an imaging apparatus 1) according to an embodiment. The imaging apparatus 1 includes a pixel array 11, a drive section 12, a readout section 13, a signal processing section 14, and an imaging control section 15.

The pixel array 11 includes a plurality of light-receiving pixels P arranged in matrix. The light-receiving pixel P is configured to generate a signal SIG including a pixel voltage Vpix in response to a received light amount.

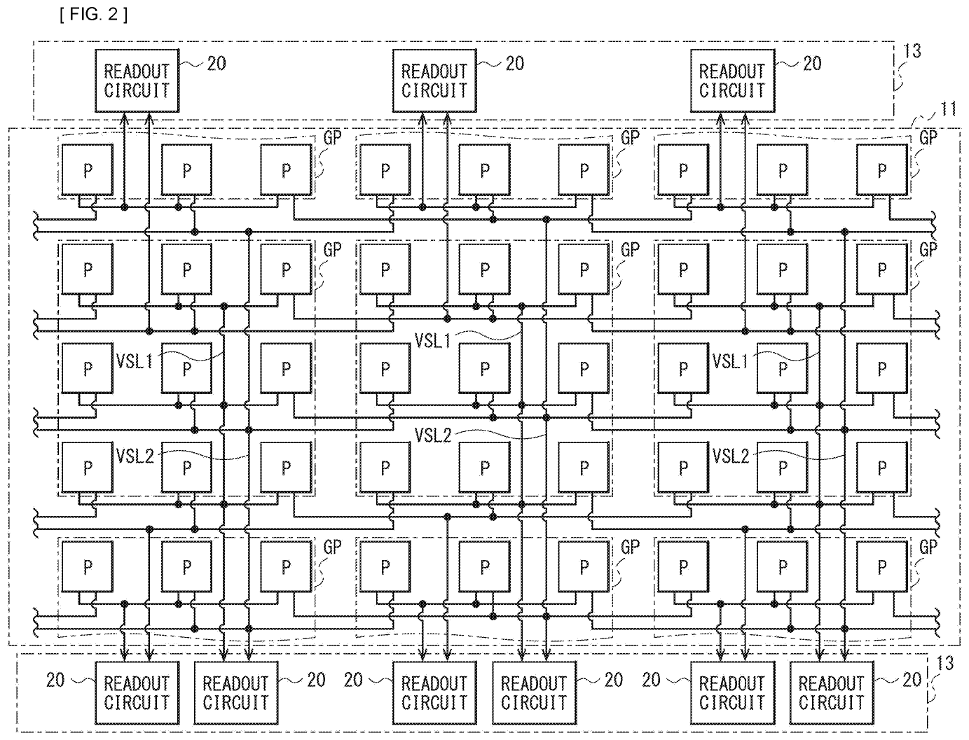

FIG. 2 illustrates a configuration example of the pixel array 11. The plurality of light-receiving pixels P in the pixel array 11 is divided into a plurality of pixel groups GP. In this example, each of the plurality of pixel groups GP includes nine light-receiving pixels P for the sake of description. However, in reality, each of the plurality of pixel groups GP can include several hundred light-receiving pixels P, for example, as described later. This FIG. 2 illustrates nine pixel groups GP among the plurality of pixel groups GP.

The pixel array 11 includes a plurality of signal lines VSL1 and a plurality of signal lines VSL2. The signal line VSL1 and the signal line VSL2 are configured to transmit, to the readout section 13, the signal SIG including the pixel voltage Vpix in response to a received light amount. The imaging apparatus 1 has an operation mode M1 and an operation mode M2; the signal line VSL1 is used in the operation mode M1, and the signal line VSL2 is used in the operation mode M2.

The signal lines VSL1 are provided respectively to correspond to the pixel groups GP. The signal lines VSL1 are coupled to nine light-receiving pixels P in this example.

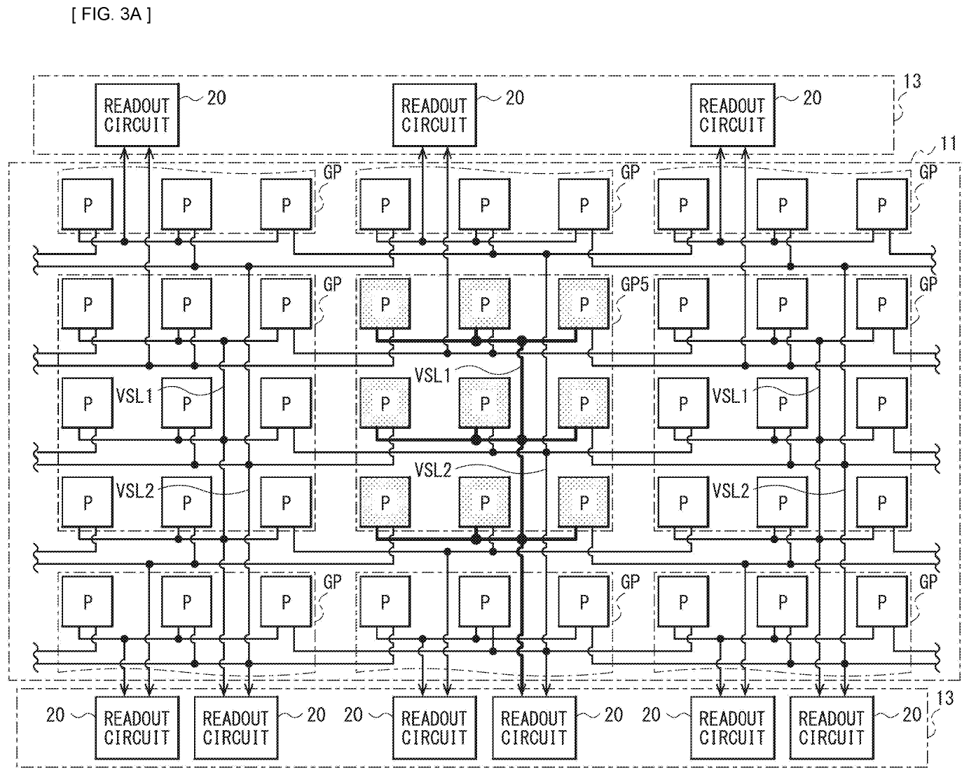

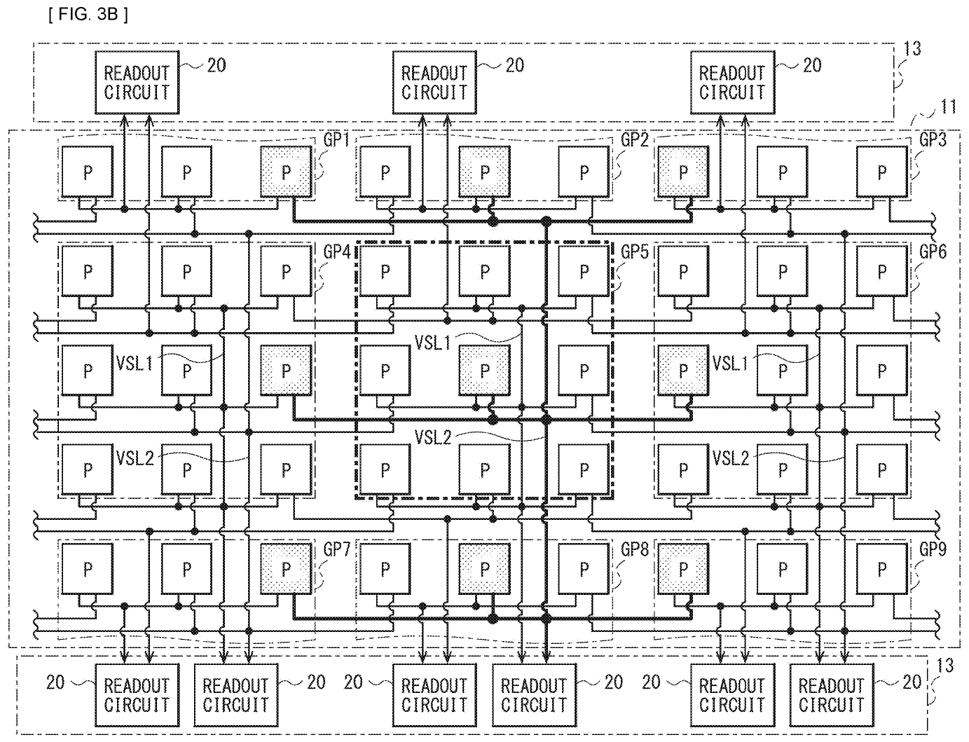

FIG. 3A illustrates an example of arrangement of the light-receiving pixels P coupled to the signal lines VSL1. This FIG. 3A focuses attention on a certain one pixel group GP (a pixel group GP5) among the plurality of pixel groups GP. In addition, the signal line VSL1 corresponding to the pixel group GP5 is indicated by a thick line, and the nine light-receiving pixels P coupled to the signal line VSL1 are indicated by shading. The signal line VSL1 corresponding to this pixel group GP5 is coupled to all of light-receiving pixels P belonging to the pixel group GP5. In addition, in the operation mode M1, these nine light-receiving pixels P supply a readout circuit 20 (described later) of the readout section 13 with the signal line VSL1 including the pixel voltage Vpix in response to a received light amount via the signal line VSL1.

The signal lines VSL2 are coupled to nine light-receiving pixels P in this example. The nine light-receiving pixels P coupled to the signal line VSL2 differ from the nine light-receiving pixels P coupled to the signal line VSL1.

FIG. 3B illustrates an example of arrangement of the light-receiving pixels P coupled to the signal lines VSL2. In this FIG. 3B, the signal line VSL2 corresponding to the pixel group GP5 is indicated by a thick line, and nine light-receiving pixels P coupled to the signal line VSL2 are indicated by shading. The signal line VSL2 corresponding the pixel group GP5 is coupled to nine light-receiving pixels P belonging to nine pixel groups GP (pixel groups GP1 to GP9) in three rows and three columns, in which the pixel group GP5 is arranged at the middle. In this example, the signal line VSL2 corresponding to the pixel group GP5 is coupled to: a lower right light-receiving pixel P in a pixel group GP (a pixel group GP1) on the upper left of the pixel group GP5; a lower middle light-receiving pixel P in a pixel group GP (a pixel group GP2) on the upper of the pixel group GP5; a lower left light-receiving pixel P in a pixel group GP (a pixel group GP3) on the upper right of the pixel group GP; a right middle light-receiving pixel P in a pixel group GP4 on the left of the pixel group GP5; a light-receiving pixel P at the middle of the pixel group GP5; a left middle light-receiving pixel P in a pixel group GP (a pixel group GP6) on the right of the pixel group GP5; an upper right light-receiving pixel P in a pixel group GP (a pixel group GP7) on the lower left of the pixel group GP5; an upper middle light-receiving pixel P in a pixel group GP (a pixel group GP8) on the lower of the pixel group GP5; and an upper left light-receiving pixel P in a pixel group GP (a pixel group GP9) on the lower right of the pixel group GP. In addition, in the operation mode M2, these nine light-receiving pixels P supply the readout circuit 20 (described later) of the readout section 13 with the signal SIG including the pixel voltage Vpix in response to a received light amount via the signal line VSL2.

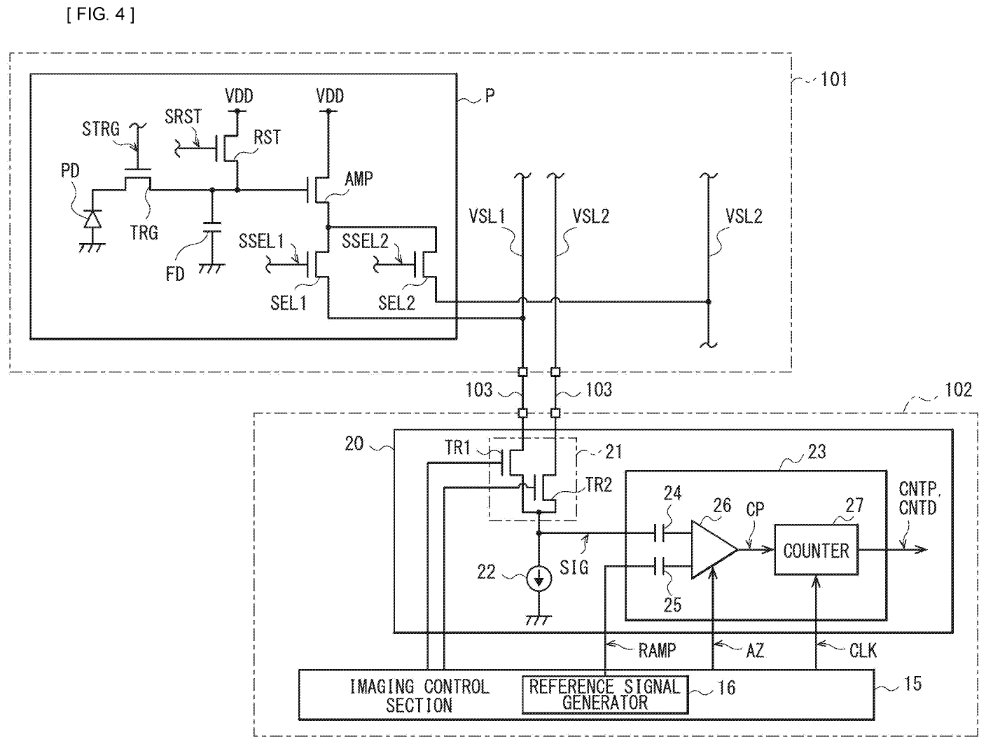

FIG. 4 illustrates a configuration example of the light-receiving pixel P. The light-receiving pixel P is provided in a semiconductor substrate 101, as described later. The light-receiving pixel P includes a photodiode PD, a transistor TRG, a floating diffusion FD, and transistors RST, AMP, SEL1, and SEL2. The transistors TRG, RST, AMP, SEL1, and SEL2 are each an N-type MOS (Metal Oxide Semiconductor) transistor in this example.

The photodiode PD is a photoelectric conversion element that generates electric charge of an amount corresponding to a received light amount and accumulates therein the generated electric charge. An anode of the photodiode PD is grounded, and a cathode thereof is coupled to a source of the transistor TRG.

A gate of the transistor TRG is supplied with a control signal STRG by the drive section 12, the source thereof is coupled to the cathode of the photodiode PD, and a drain thereof is coupled to the floating diffusion FD.

The floating diffusion FD is configured to accumulate electric charge transferred from the photodiode PD via the transistor TRG. The floating diffusion FD is configured using, for example, a diffusion layer formed on a surface of the semiconductor substrate. In FIG. 4, the floating diffusion FD is indicated by using a symbol of a capacitor.

A gate of the transistor RST is supplied with a control signal SRST by the drive section 12, a drain thereof is supplied with a power supply voltage VDD, and a source thereof is coupled to the floating diffusion FD. It is to be noted that the drain of the transistor RST is supplied with the power supply voltage VDD in this example, but this is not limitative; the drain of the transistor RST can be supplied with a predetermined direct-current voltage.

A gate of the transistor AMP is coupled to the floating diffusion FD, a drain thereof is supplied with the power supply voltage VDD, and a source thereof is coupled to a drain of the transistor SEL1 and a drain of the transistor SEL2.

A gate of the transistor SEL1 is supplied with a control signal SSEL1 by the drive section 12, the drain thereof is coupled to the source of the transistor AMP, and a source thereof is coupled to the signal line VSL1. A gate of the transistor SEL2 is supplied with a control signal SSEL2 by the drive section 12, the drain thereof is coupled to the source of the transistor AMP, and a source thereof is coupled to the signal line VSL2. The signal line VSL1 coupled to the source of the transistor SEL1 and the signal line VSL2 coupled to the source of the transistor SEL2 are respectively coupled to different readout circuits 20, for example, as illustrated in FIGS. 3A and 3B.

This configuration brings the transistors TRG and RST into an ON state on the basis of the control signals STRG and SRST, for example, in the light-receiving pixel P, thereby discharging electric charge accumulated in the photodiode PD. Then, these transistors TRG and RST are brought into an OFF state, whereby an exposure period is started, allowing electric charge of an amount corresponding to a received light amount to be accumulated in the photodiode PD. Then, after the end of the exposure period, the light-receiving pixel P outputs the signal SIG including a reset voltage Vreset and the pixel voltage Vpix to the signal line VSL1 or the signal line VSL2. The light-receiving pixel P outputs the signal SIG to the signal line VSL1 in the operation mode M1, and outputs the signal SIG to the signal line VSL2 in the operation mode M2.

Specifically, in the operation mode M1, first, the transistor SEL1 is brought into an ON state on the basis of the control signal SSEL1 to thereby allow the light-receiving pixel P to be electrically coupled to the signal line VSLL. This allows the transistor AMP to be coupled to a constant current source 22 (described later) of the readout section 13 and to operate as a so-called source follower. As described later, during a P-phase (Pre-charge phase) period TP after resetting of a voltage of the floating diffusion FD as a result of the transistor RST being brought into an ON state, the light-receiving pixel P outputs, as the reset voltage Vreset, a voltage corresponding to the voltage of the floating diffusion FD at that time. In addition, during a D-phase (Data phase) period TD after transfer of electric charge from the photodiode PD to the floating diffusion FD as a result of the transistor RST being brought into the ON state, the light-receiving pixel P outputs, as the pixel voltage Vpix, a voltage corresponding to the voltage of the floating diffusion FD at that time. The difference voltage between the pixel voltage Vpix and the reset voltage Vreset corresponds to a received light amount of the light-receiving pixel P. In this manner, the light-receiving pixel P outputs the signal SIG including these reset voltage Vreset and pixel voltage Vpix to the signal line VSL1. The same applies to the operation mode M2, in which the light-receiving pixel P outputs the signal SIG including the reset voltage Vreset and the pixel voltage Vpix to the signal line VSL2.

The drive section 12 (FIG. 1) is configured to drive the plurality of light-receiving pixels P in the pixel array 11 on the basis of an instruction from the imaging control section 15. Specifically, the drive section 12 supplies the control signals STRG, SRST, SSEL1, and SSEL2 to each of the plurality of light-receiving pixels P in the pixel array 11 to thereby drive the plurality of light-receiving pixels P in the pixel array 11.

The readout section 13 is configured to generate an image signal Spic0 by performing AD conversion on the basis of the signal SIG supplied from the pixel array 11 via the signal line VSL1 or the signal line VSL2 and on the basis of an instruction from the imaging control section 15. As illustrated in FIG. 2, the readout section 13 includes a plurality of readout circuits 20. The readout circuits 20 are provided respectively to correspond to the pixel groups GP in the pixel array 11.

As illustrated in FIG. 4, the readout circuit 20 includes a switch 21, the constant current source 22, and an AD converter 23. The readout circuit 20 is provided in a semiconductor substrate 102 as described later.

The switch 21 is coupled to the signal lines VSL1 and VSL2 in a pixel group GP corresponding to the readout circuit 20, and is configured to couple the signal line VSL1 and the signal line VSL2 to the AD converter 23. The switch 21 includes two transistors TR1 and TR2. The transistors TR1 and TR2 are each an N-type MOS transistor. A gate of the transistor TR1 is supplied with a control signal from the imaging control section 15, a drain thereof is coupled to the signal line VSL1, and a source thereof is coupled to the constant current source 22 and is coupled to the AD converter 23. A gate of the transistor TR2 is supplied with a control signal from the imaging control section 15, a drain thereof is coupled to the signal line VSL2, and a source thereof is coupled to the constant current source 22 and is coupled to the AD converter 23.

This configuration allows, in a case where the operation mode M of the imaging apparatus 1 is the operation mode M1, the transistor TR1 to be brought into an ON state and the transistor TR2 to be brought into an OFF state. This allows the switch 21 to couple the signal line VSL1 to the AD converter 23 and to supply the AD converter 23 with the signal SIG supplied from the light-receiving pixel P via the signal line VSL1. In addition, in a case where the operation mode M of the imaging apparatus 1 is the operation mode M2, the transistor TR2 is brought into an ON state, and the transistor TR1 is brought into an OFF state. This allows the switch 21 to couple the signal line VSL2 to the AD converter 23 and to supply the AD converter 23 with the signal SIG supplied from the light-receiving pixel P via the signal line VSL2.

The constant current source 22 is configured to flow a predetermined current to one of the signal lines VSL1 and VSL2 selected by the switch 21. One end of the constant current source 22 is coupled to the switch 21, and the other end thereof is grounded.

The AD converter 23 is configured to perform AD conversion on the basis of the signal SIG supplied from the light-receiving pixel P via the signal line VSL1 or the signal line VSL2. The AD converter 23 includes capacitors 24 and 25, a comparison circuit 26, and a counter 27.

One end of the capacitor 24 is coupled to the switch 21 and is supplied with the signal SIG, and the other end thereof is coupled to the comparison circuit 26. One end of the capacitor 25 is supplied with a reference signal RAMP, and the other end thereof is coupled to the comparison circuit 26.

The comparison circuit 26 is configured to generate a signal CP by performing a comparison operation on the basis of the signal SIG supplied from the light-receiving pixel P via the capacitor 24 and the reference signal RAMP supplied from the imaging control section 15 via the capacitor 25. The comparison circuit 26 sets an operating point by setting voltages of the capacitors 24 and 25 on the basis of a control signal AZ supplied from the imaging control section 15. Thereafter, the comparison circuit 26 performs a comparison operation to compare the reset voltage Vreset included in the signal SIG and a voltage of the reference signal RAMP with each other in the P-phase period TP, and performs a comparison operation to compare the pixel voltage Vpix included in the signal SIG and the voltage of the reference signal RAMP with each other in the D-phase period TD.

The counter 27 is configured to perform a count operation to count pulses of a clock signal CLK supplied from the imaging control section 15 on the basis of the signal CP supplied from the comparison circuit 26. Specifically, in the P-phase period TP, the counter 27 counts pulses of the clock signal CLK until transition of the signal CP to thereby generate a count value CNTP and output this count value CNTP. In addition, in the D-phase period TD, the counter 27 counts pulses of the clock signal CLK until transition of the signal CP to thereby generate a count value CNTD and output this count value CNTD.

In this manner, each of a plurality of AD converters 23 in the readout section 13 generates the count values CNTP and CNTD. Then, the readout section 13 sequentially transfers, to the signal processing section 14, these count values CNTP and CNTD as the image signal Spic0. It is to be noted that the AD converter 23 includes the capacitors 24 and 25, the comparison circuit 26, and the counter 27 in this example; however, this is not limitative. For example, the capacitors 24 and 25 may be omitted. In addition, the AD converter 23 may have another circuit configuration.

The signal processing section 14 (FIG. 1) is configured to generate an image signal Spic by performing predetermined signal processing on the basis of the image signal Spic0 and an instruction from the imaging control section 15. Predetermined image processing includes, for example, CDS (CDS; Correlated Double Sampling) processing. In the CDS processing, the signal processing section 14 generates a pixel value VAL by utilizing the principle of correlated double sampling on the basis of the count value CNTP obtained in the P-phase period TP and the count value CNTD obtained in the D-phase period TD which are included in the image signal Spic0. Then, in response to the operation mode M, the signal processing section 14 generates a frame image by arranging pixel values VAL. That is, as illustrated in FIGS. 3A and 3B, the operation mode M1 and the operation mode M2 differ from each other in positions of the nine light-receiving pixels P that supply the signal SIG to the readout circuit 20. Therefore, the signal processing section 14 arranges the pixel values VAL in response to the positions of the light-receiving pixels P to thereby generate a frame image.

The imaging control section 15 (FIG. 1) is configured to control the operations of the imaging apparatus 1 by supplying a control signal to the drive section 12, the readout section 13, and the signal processing section 14 and controlling operations of the circuits thereof.

The imaging control section 15 includes a reference signal generator 16. The reference signal generator 16 is configured to generate the reference signal RAMP. The reference signal RAMP has a so-called ramp waveform in which a voltage level gradually changes as time elapses during periods (P-phase period TP and D-phase period TD) in which the AD converter 23 performs AD conversion. The reference signal generator 16 supplies such a reference signal RAMP to the readout section 13.

Next, description is given of an example of implementation of the imaging apparatus 1.

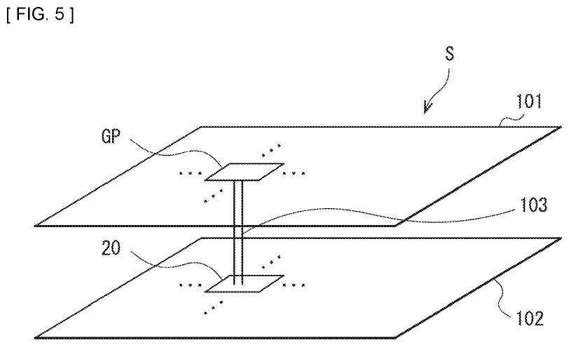

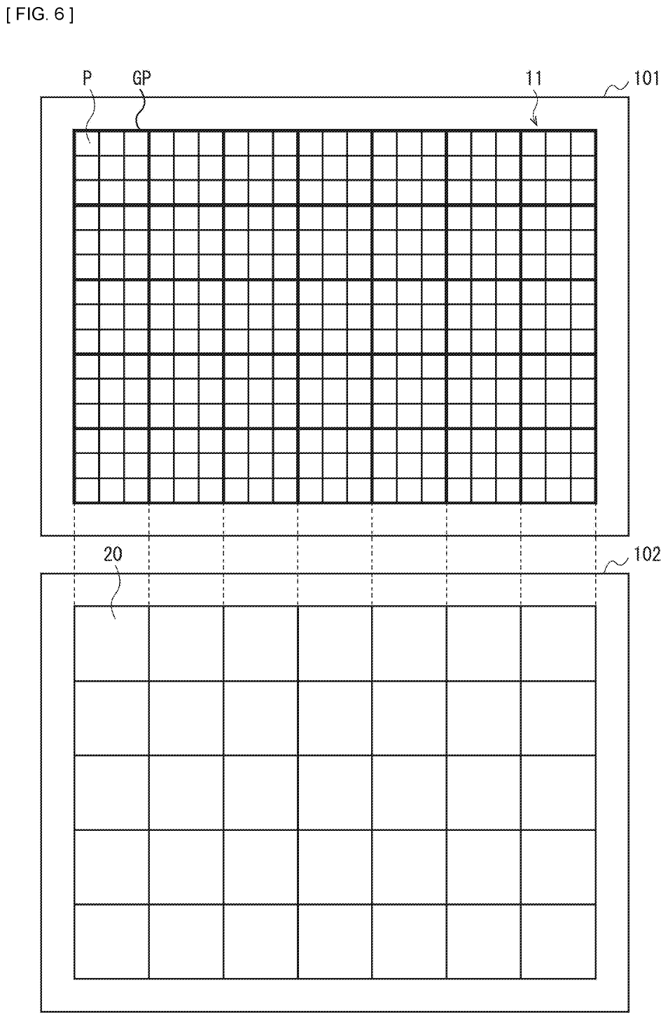

FIGS. 5 and 6 each illustrate an example of implementation of the imaging apparatus 1. The imaging apparatus 1 is formed in two sheets of the semiconductor substrates 101 and 102 in this example. The semiconductor substrate 101 is disposed on a side of a light-receiving surface S of the imaging apparatus 1, and the semiconductor substrate 102 is disposed on a side opposite to the side of the light-receiving surface S of the imaging apparatus 1. The semiconductor substrates 101 and 102 overlap each other. In the semiconductor substrate 101, for example, the pixel array 11 is disposed, and in the semiconductor substrate 102, the drive section 12, the readout section 13, the signal processing section 14, and the imaging control section 15 are disposed. A wiring line of the semiconductor substrate 101 and a wiring line of the semiconductor substrate 102 are coupled by a wiring line 103. For example, the wiring line 103 may use metallic bond such as Cu—Cu.

As illustrated in FIGS. 5 and 6, the semiconductor substrate 101 is provided with a plurality of light-receiving pixels P arranged side by side, and the semiconductor substrate 102 is provided with a plurality of readout circuits 20 arranged side by side. The readout circuit 20 is arranged in a region, of the semiconductor substrate 102, corresponding to the region in which the pixel group GP is arranged. As illustrated in FIGS. 4 and 5, the signal lines VSL1 and VSL2 of the pixel group GP and the readout circuit 20 are coupled together by the wiring line 103.

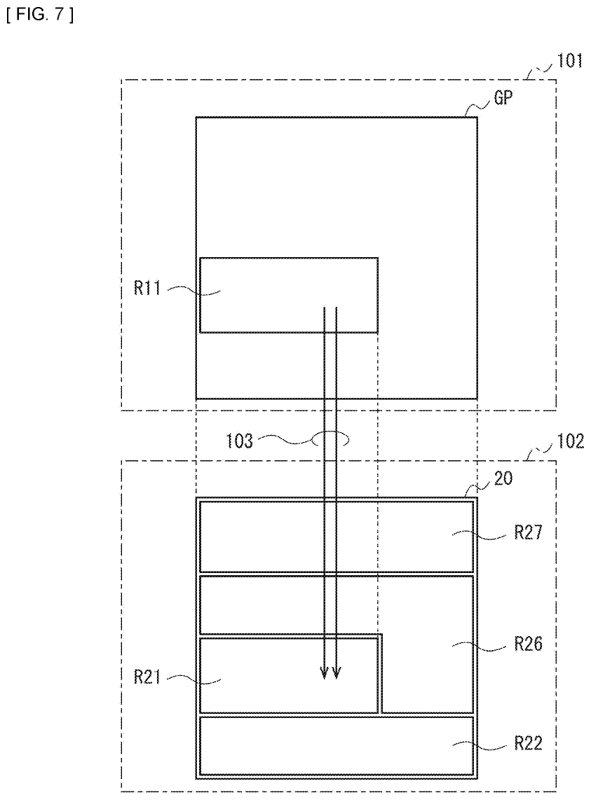

FIG. 7 illustrates an example of arrangement of the switch 21, the constant current source 22, the comparison circuit 26, and the counter 27 in the region in which the readout circuit 20 is arranged. In the semiconductor substrate 101, the region in which the pixel group GP is arranged includes a region R11. This region R11 is a region for performing the metallic bond such as Cu—Cu with respect to the semiconductor substrate 102. In the semiconductor substrate 102, the region in which the readout circuit 20 is arranged includes regions R21, R22, R26, and R27. The region R21 is a region for performing the metallic bond such as Cu—Cu with respect to the semiconductor substrate 101. This region R21 is arranged at a position corresponding to the region R11 in the semiconductor substrate 101. This allows the signal lines VSL1 and VSL2 of the pixel group GP in the semiconductor substrate 101 and the readout circuit 20 in the semiconductor substrate 102 to be coupled to each other by the wiring line 103. In addition, the switch 21 is arranged in the region R21. The region R22 is a region in which the constant current source 22 is arranged. The region R26 is a region in which the comparison circuit 26 is arranged. The region R27 is a region in which the counter 27 is arranged.

Here, the light-receiving pixel P corresponds to a specific example of a “light-receiving pixel” in the present disclosure. The pixel array 11 corresponds to a specific example of a “pixel array” in the present disclosure. The AD converter 23 corresponds to a specific example of an “AD converter” in the present disclosure. The readout section 13 corresponds to a specific example of a “readout section” in the present disclosure. The operation mode M1 corresponds to a specific example of a “first operation mode” in the present disclosure. The operation mode M2 corresponds to a specific example of a “second operation mode” in the present disclosure. The semiconductor substrate 101 corresponds to a specific example of a “first semiconductor substrate” in the present disclosure. The semiconductor substrate 102 corresponds to a specific example of a “second semiconductor substrate” in the present disclosure.

### [Operations and Workings]

Now, description is given of operations and workings of the imaging apparatus 1 of the present embodiment.

### (Overview of Overall Operations)

First, description is given of an overview of overall operations of the imaging apparatus 1 with reference to FIG. 1. The drive section 12 drives the plurality of light-receiving pixels P in the pixel array 11 on the basis of an instruction from the imaging control section 15. The light-receiving pixel P outputs the reset voltage Vreset as the signal SIG in the P-phase period TP, and outputs the pixel voltage Vpix in response to a received light amount as the signal SIG in the D-phase period TD. The readout section 13 generates the image signal Spic0 on the basis of the signal SIG supplied from the pixel array 11 via the signal line VSL1 or the signal line VSL2. The signal processing section 14 performs predetermined image processing on the basis of the image signal Spic0 to thereby generate the image signal Spic. The imaging control section 15 controls the operations of the imaging apparatus 1 by supplying a control signal to the drive section 12, the readout section 13, and the signal processing section 14 and controlling operations of the circuits thereof.

### (Detailed Operations)

Description is given below of a read operation on the light-receiving pixel P in the operation mode M1. It is to be noted that the same applies to a read operation in the operation mode M2.

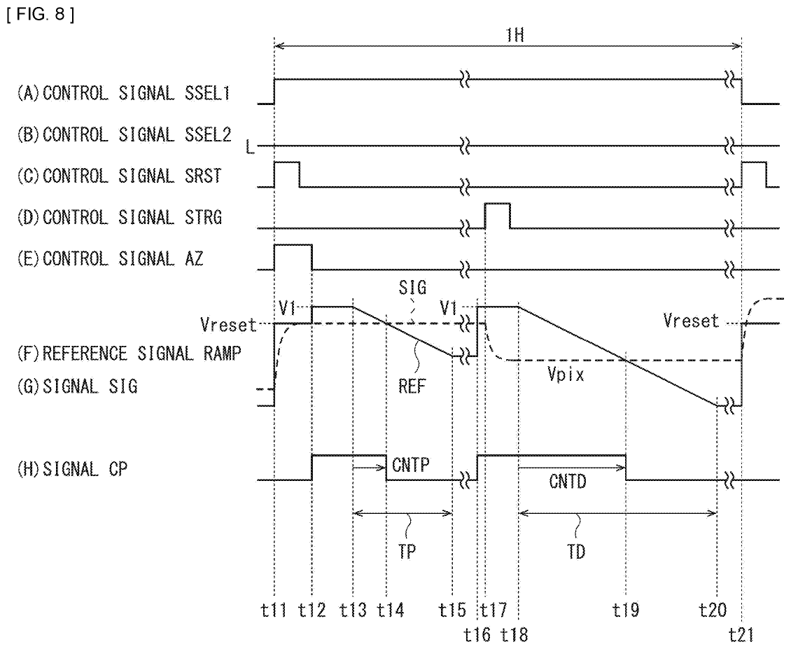

FIG. 8 illustrates an example of the read operation, in which (A) indicates a waveform of the control signal SSEL1, (B) indicates a waveform of the control signal SSEL2, (C) indicates a waveform of the control signal SRST, (D) indicates a waveform of the control signal STRG, (E) indicates a waveform of the control signal AZ, (F) indicates a waveform of the reference signal RAMP, (G) indicates a waveform of the signal SIG, and (H) indicates a waveform of the signal CP. (F) and (G) of FIG. 8 indicate waveforms of the reference signal RAMP and the signal SIG using the same voltage axis. In addition, in this description, the waveform of the reference signal RAMP indicated in (F) of FIG. 8 is a waveform of a voltage supplied to an input terminal of the comparison circuit 26 via the capacitor 24, and the waveform of the signal SIG indicated in (G) of FIG. 8 is a waveform of a voltage supplied to the input terminal of the comparison circuit 26 via the capacitor 25. In the case of the operation mode M1, the control signal SSEL2 is fixed to a low level ((B) of FIG. 8).

First, at a timing t11, a horizontal period H starts. This causes the drive section 12 to change a voltage of the control signal SSEL1 from a low level to a high level ((A) of FIG. 8). This brings the transistor SEL1 into an ON state in the light-receiving pixel P to cause the light-receiving pixel P to be electrically coupled to the signal line VSL1. In addition, at this timing t11, the drive section 12 changes a voltage of the control signal SRST from a low level to a high level ((C) of FIG. 8). This brings the transistor RST into an ON state in the light-receiving pixel P to cause the voltage of the floating diffusion FD to be set to the power supply voltage VDD (reset operation). Then, the light-receiving pixel P outputs a voltage corresponding to the voltage of the floating diffusion FD at this time. In addition, at this timing t11, the imaging control section 15 changes a voltage of the control signal AZ from a low level to a high level ((E) of FIG. 8). This allows the comparison circuit 26 of the AD converter 23 to set an operating point by setting the voltages of the capacitors 24 and 25. In this manner, the voltage of the signal SIG is set to the reset voltage Vreset, and the voltage of the reference signal RAMP is set to the same voltage as the voltage (reset voltage Vreset) of the signal SIG ((F) and (G) of FIG. 8).

Then, at a timing when predetermined time has elapsed from the timing t11, the drive section 12 changes the voltage of the control signal SRST from a high level to a low level ((C) of FIG. 8). This brings the transistor RST into an OFF state in the light-receiving pixel P to finish the reset operation.

Next, at a timing t12, the imaging control section 15 changes the voltage of the control signal AZ from a high level to a low level ((E) of FIG. 8). This allows the comparison circuit 26 to finish the setting of the operating point.

In addition, at this timing t12, the reference signal generator 16 sets the voltage of the reference signal RAMP to the voltage V1 ((F) of FIG. 8). This causes the voltage of the reference signal RAMP to be higher than the voltage of the signal SIG, thus allowing the comparison circuit 26 to change a voltage of the signal CP from a low level to a high level ((H) of FIG. 8).

Then, during a period of timings t13 to t15 (P-phase period TP), the AD converter 23 performs AD conversion on the basis of the signal SIG. Specifically, first, at a timing t13, the reference signal generator 16 starts lowering the voltage of the reference signal RAMP in a predetermined degree of change from the voltage V1 ((F) of FIG. 8). In addition, at this timing t13, the imaging control section 15 starts generating the clock signal CLK. The counter 27 of the AD converter 23 performs a count operation to thereby count pulses of the clock signal CLK.

Then, at a timing t14, the voltage of the reference signal RAMP falls below the voltage (reset voltage Vreset) of the signal SIG ((F) and (G) of FIG. 8). This allows the comparison circuit 26 of the AD converter 23 to change the voltage of the signal CP from a high level to a low level ((H) of FIG. 8). The counter 27 of the AD converter 23 stops the count operation on the basis of transition of the signal CP. The count value (count value CNTP) of the counter 27 at this time is a value corresponding to the reset voltage Vreset.

Next, at a timing t15, the imaging control section 15 stops the generation of the clock signal CLK upon the end of the P-phase period TP. In addition, at this timing t15, the reference signal generator 16 stops the change in the voltage of the reference signal RAMP ((F) of FIG. 8). Then, in the period after this timing t15, the readout section 13 supplies the signal processing section 14 with the count value CNTP of the counter 27 as the image signal Spic0. Then, the counter 27 resets the count value.

Next, at a timing t16, the imaging control section 15 sets the voltage of the reference signal RAMP to the voltage V1 ((F) of FIG. 8). This causes the voltage of the reference signal RAMP to be higher than the voltage (reset voltage Vreset) of the signal SIG, thus allowing the comparison circuit 26 to change the voltage of the signal CP from a low level to a high level ((H) of FIG. 8).

Next, at a timing t17, the drive section 12 changes a voltage of the control signal STRG from a low level to a high level ((D) of FIG. 8). This brings the transistor TRG into an ON state in the light-receiving pixel P, thus allowing electric charge generated in the photodiode PD to be transferred to the floating diffusion FD (electric charge transfer operation). Then, the light-receiving pixel P outputs a voltage corresponding to the voltage of the floating diffusion FD at this time. This allows the voltage of the signal SIG to be the pixel voltage Vpix ((G) of FIG. 8).

Then, at a timing when predetermined time has elapsed from the timing t17, the drive section 12 changes the voltage of the control signal STRG from a high level to a low level ((D) of FIG. 8). This brings the transistor TRG into an OFF state in the light-receiving pixel P to finish the electric charge transfer operation.

Then, during a period of timings t18 to t20 (D-phase period TD), the AD converter 23 performs AD conversion on the basis of the signal SIG. Specifically, first, at a timing t18, the reference signal generator 16 starts lowering the voltage of the reference signal RAMP in a predetermined degree of change from the voltage V1 ((F) of FIG. 8). In addition, at this timing t18, the imaging control section 15 starts generating the clock signal CLK. The counter 27 of the AD converter 23 performs a count operation to thereby count pulses of the clock signal CLK.

Then, at a timing t19, the voltage of the reference signal RAMP falls below the voltage (pixel voltage Vpix) of the signal SIG ((F) and (G) of FIG. 8). This allows the comparison circuit 26 of the AD converter 23 to change the voltage of the signal CP from a high level to a low level ((H) of FIG. 8). The counter 27 of the AD converter 23 stops the count operation on the basis of transition of the signal CP. The count value (count value CNTD) of the counter 27 at this time is a value corresponding to the pixel voltage Vpix.

Next, at a timing t20, the imaging control section 15 stops the generation of the clock signal CLK upon the end of the D-phase period TD. In addition, at this timing t20, the reference signal generator 16 stops the change in the voltage of the reference signal RAMP ((F) of FIG. 8). Then, in the period after this timing t20, the readout section 13 supplies the signal processing section 14 with the count value CNTD of the counter 27 as the image signal Spic0. Then, the counter 27 resets the count value.

Next, at a timing t21, the drive section 12 changes the voltage of the control signal SSEL1 from a high level to a low level ((A) of FIG. 8). This brings the transistor SEL1 into an OFF state in the light-receiving pixel P, thus causing the light-receiving pixel P to be electrically decoupled from the signal line VSL1.

In this manner, the readout section 13 supplies the signal processing section 14 with the image signal Spic0 including the count values CNTP and CNTD. The signal processing section 14 generates the pixel value VAL by utilizing the principle of correlated double sampling on the basis of the count values CNTP and CNTD included in the image signal Spic0, for example. Specifically, the signal processing section 14 generates the pixel value VAL by subtracting the count value CNTP from the count value CNTD, for example. Then, in response to the operation mode M, the signal processing section 14 generates a frame image by arranging the pixel values VAL. That is, as illustrated in FIGS. 3A and 3B, the operation mode M1 and the operation mode M2 differ from each other in positions of nine light-receiving pixels P that supply the signal SIG to the readout circuit 20. Therefore, the signal processing section 14 arranges the pixel values VAL in response to the positions of the light-receiving pixels P to thereby generate a frame image. Then, the signal processing section 14 generates the image signal Spic including image data of this frame image.

### (Operations in Operation Modes M1 And M2)

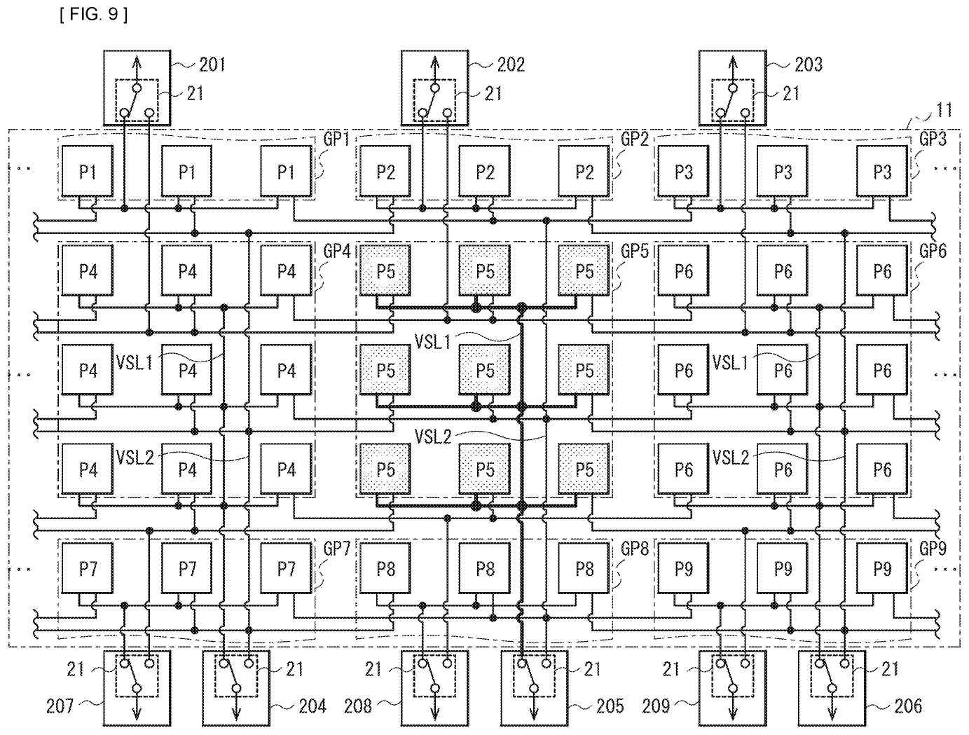

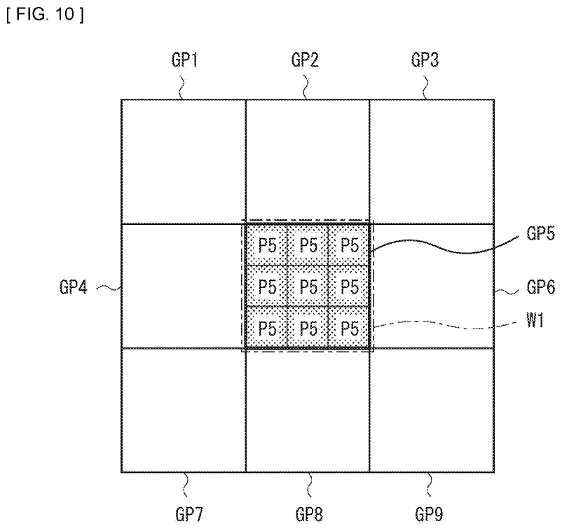

FIGS. 9 and 10 each illustrate an operation example of the imaging apparatus 1 in the operation mode M1. Nine readout circuits 20 (readout circuits 201 to 209) correspond to nine pixel groups GP (pixel groups GP1 to GP9), respectively. Each of the readout circuits 201 to 209 includes the switch 21. In this FIG. 9, the light-receiving pixel P is indicated by light-receiving pixels P1 to P9. The light-receiving pixel P1 is the light-receiving pixel P that supplies the signal SIG to the readout circuit 201. The light-receiving pixel P2 is the light-receiving pixel P that supplies the signal SIG to the readout circuit 202. The same applies also to the light-receiving pixels P3 to P9.

For example, the signal line VSL1 corresponding to the pixel group GP5 is coupled to all of the light-receiving pixels P (light-receiving pixels P5) belonging to this pixel group GP5. In the operation mode M1, the nine light-receiving pixels P5 output the signal SIG to the signal line VSL1. The switch 21 of a readout circuit 205 couples the signal line VSL1, among the signal line VSL1 and the signal line VSL2, to the AD converter 23. In this manner, the AD converter 23 of the readout circuit 205 performs AD conversion on the basis of the signals SIG supplied from the nine light-receiving pixels P5 illustrated in FIG. 9.

As illustrated in FIG. 10, the nine light-receiving pixels P (light-receiving pixels P5) to be subject to a read operation of the readout circuit 205 are nine light-receiving pixels P belonging to the pixel group GP5. That is, in this case, a region W1 to be subject to a read operation of the readout circuit 205 is the same as the region of the pixel group GP5.

Such an operation mode M1 can be used, for example, when performing an ROI (Region Of Interest) operation. That is, there may be a case, in an imaging operation, where only an image of a particular region is desired to be obtained, for example. In that case, by operating the readout circuit 20 corresponding to the particular region, among the plurality of readout circuits 20, it is possible to obtain only an image of the particular region while reducing power consumption.

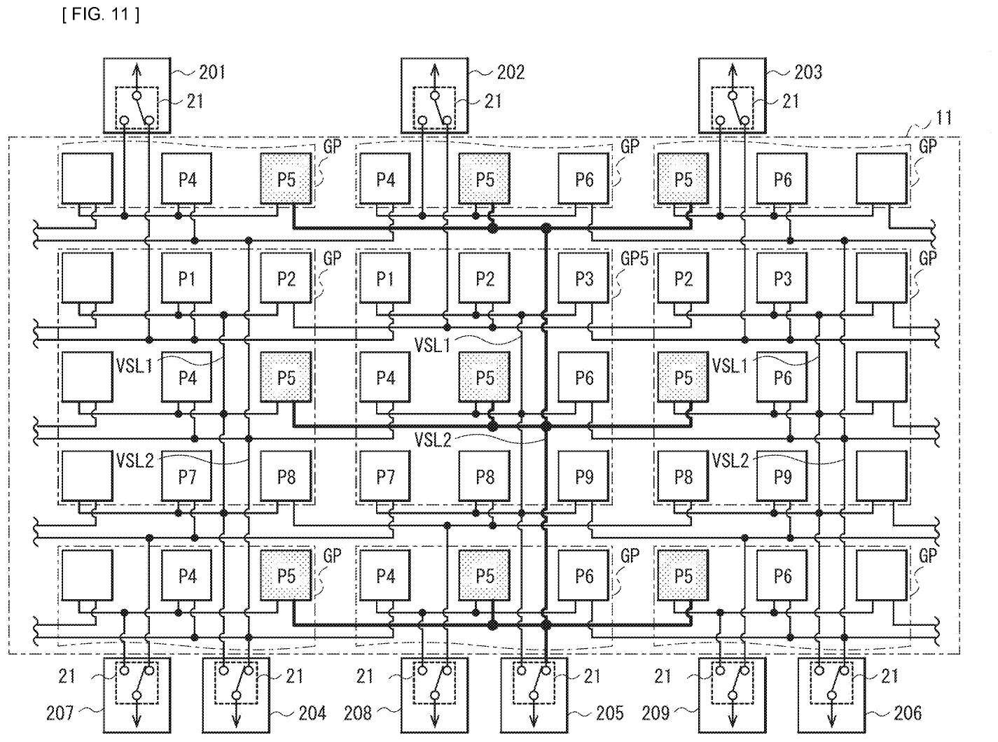

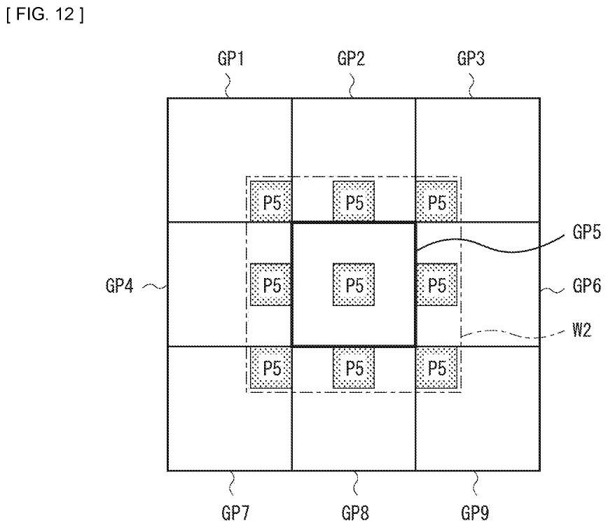

FIGS. 11 and 12 each illustrate an operation example of the imaging apparatus 1 in the operation mode M2. For example, the signal line VSL2 corresponding to the pixel group GP5 is coupled to the nine light-receiving pixels P (light-receiving pixels P5) belonging to nine pixel groups GP (pixel groups GP1 to GP9) in three rows and three columns, in which the pixel group GP5 is arranged at the middle. In the operation mode M2, the nine light-receiving pixels P5 output the signal SIG to the signal line VSL2. The switch 21 of the readout circuit 205 couples the signal line VSL2, among the signal line VSL1 and the signal line VSL2, to the AD converter 23. In this manner, the AD converter 23 of the readout circuit 205 performs AD conversion on the basis of the signals SIG supplied from the nine light-receiving pixels P5 illustrated in FIG. 11.

As illustrated in FIG. 12, the nine light-receiving pixels P (light-receiving pixel P5) to be subject to the read operation of the readout circuit 205 are nine light-receiving pixels P belonging to nine pixel groups GP in three rows and three columns, in which the pixel group GP5 is arranged at the middle. That is, in this case, a region W2 to be subject to a read operation of the readout circuit 205 is wider than the region of the pixel group GP5.

As illustrated in FIG. 12, in the operation mode M2, the region W2 to be subject to the read operation of the readout circuit 20 can be wider than the region of the pixel group GP. In this case, in adjacent pixel groups GP, the regions W2 overlap each other. Consequently, as described below, it is possible, in the operation mode M2, to make a step difference in the pixel value VAL, which is caused by a characteristic difference or a quantization error between the plurality of AD converters 23, less visible than in the operation mode M1.

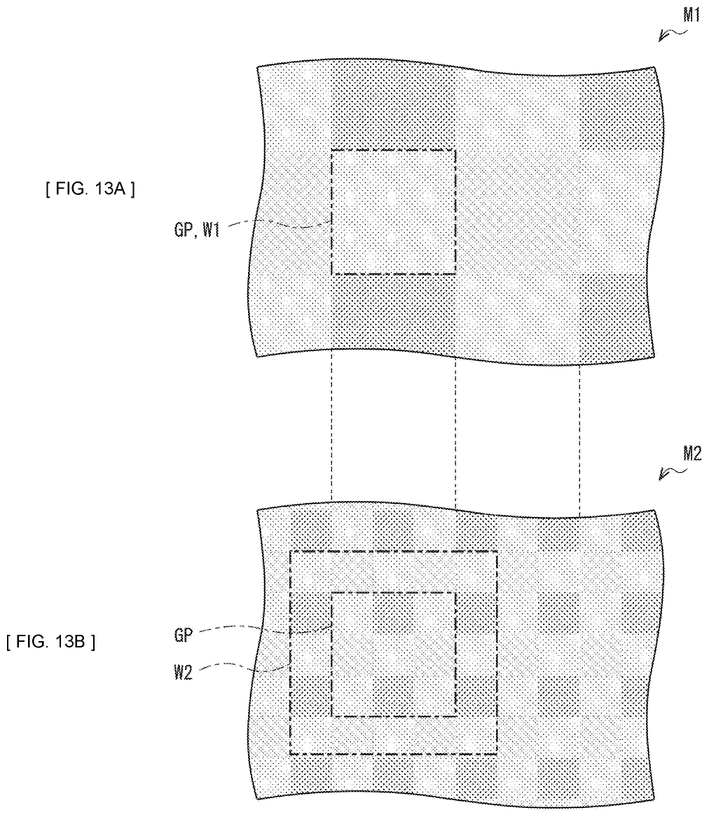

FIG. 13 illustrates an example of imaging results in a case where imaging is performed on a uniform subject, in which (A) illustrates an imaging result in the operation mode M1, and (B) illustrates an imaging result in the operation mode M2.

In this example, because imaging is performed on a uniform subject, it is expected that a uniform imaging result can be obtained. That is, because received light amounts in the plurality of light-receiving pixels P are the same, it is expected that all of the pixel values VAL would be substantially the same. However, for example, in a case where there is a characteristic difference between the plurality of AD converters 23 or in a case where there is a quantization error therebetween, a difference may occur between the pixel values VAL generated by the AD converters 23.

In the operation mode M1, the AD converter 23 in the readout circuit 20 performs AD conversion on the basis of the signals SIG generated by the nine light-receiving pixels P belonging to one pixel group GP. Therefore, as illustrated in (A) of FIG. 13, the pixel value VAL may differ from one pixel group GP to another. In this case, a step difference occurs in the pixel value VAL between one pixel group GP and another. As described above, a step difference occurs in the pixel value VAL between large units including the plurality of light-receiving pixels P, which thus may possibly cause the step difference in the pixel value VAL to be more visible.

Meanwhile, in the operation mode M2, as illustrated in FIG. 12, the AD converter 23 in the readout circuit 20 performs AD conversion on the basis of the signals SIG generated by the nine light-receiving pixels P belonging to the nine pixel groups GP. Thus, as illustrated in (B) of FIG. 13, for example, a step difference occurs in the pixel value VAL between one light-receiving pixel P and another. As described above, in the operation mode M2, a step difference occurs in the pixel value VAL between small units P, thus enabling the step difference in the pixel value VAL to be less visible.

In the above example, the pixel group GP includes the nine light-receiving pixels P for the sake of description. However, in reality, the pixel group GP can include several hundred light-receiving pixels P, for example.

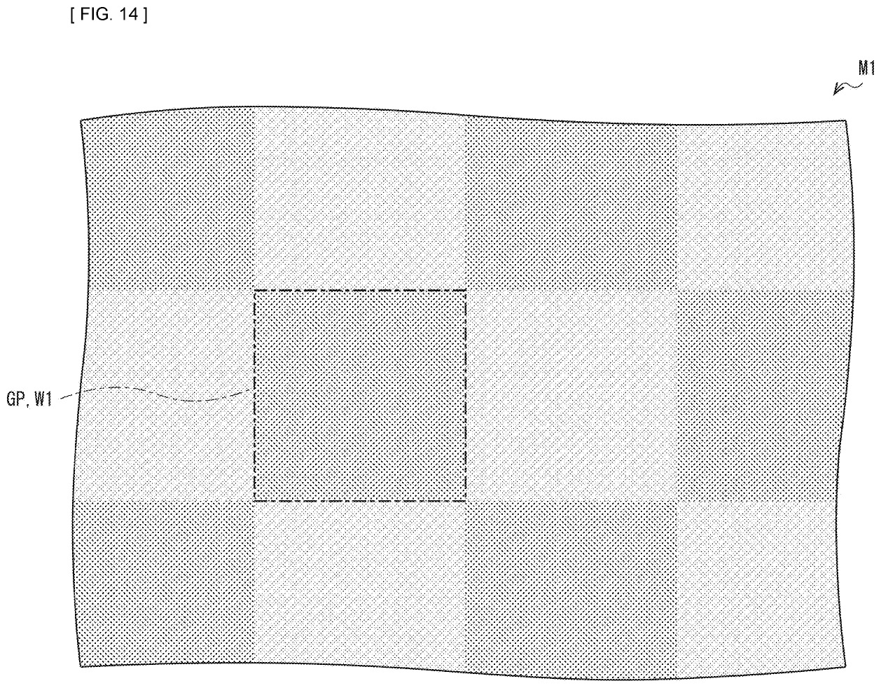

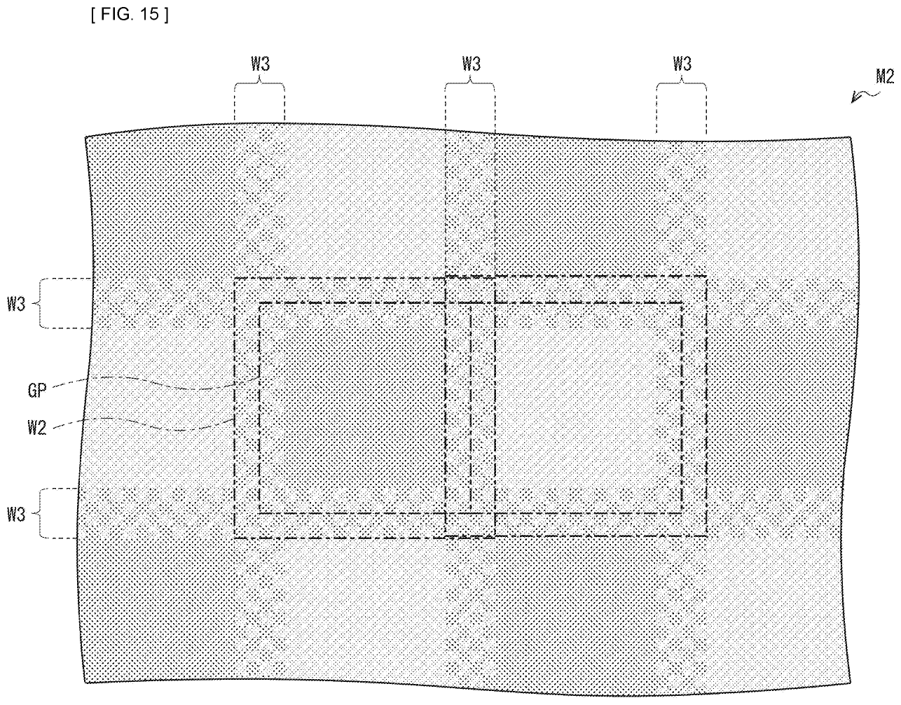

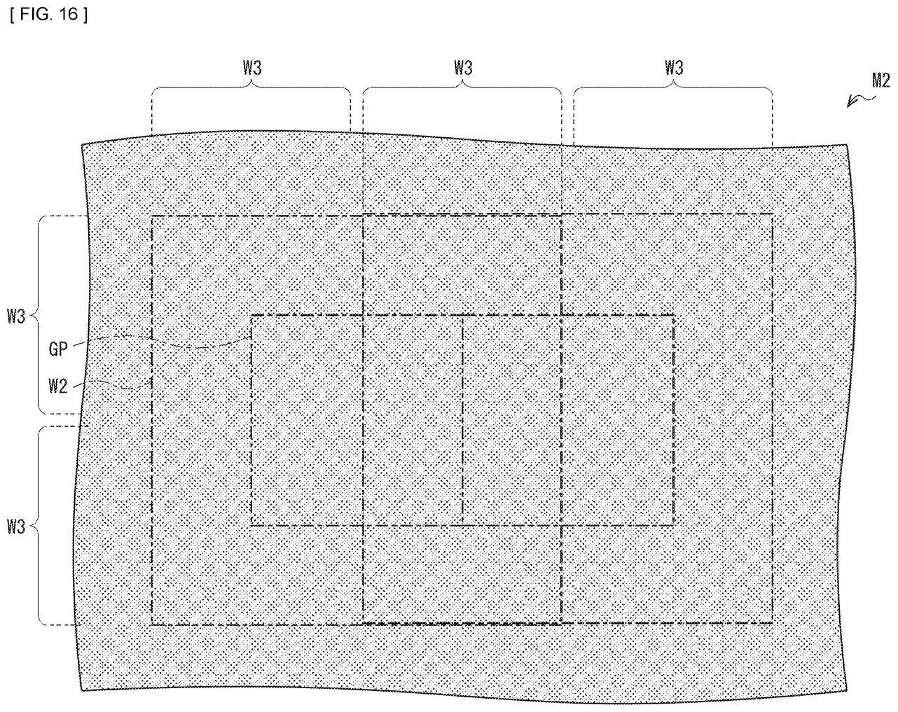

FIGS. 14 to 16 each illustrate an example of an imaging result in a case where the pixel group GP includes 289 (17×17) light-receiving pixels P. FIG. 14 illustrates an imaging result in the operation mode M1, and FIGS. 15 and 16 each illustrate an imaging result in the operation mode M2. In the example of FIG. 15, the region W2 to be subject to the read operation of the readout circuit 20 is made wider by two light-receiving pixels P than the region of the pixel group GP. In the example of FIG. 16, the region W2 to be subject to the read operation of the readout circuit 20 is made wider by eight light-receiving pixels P than the region of the pixel group GP.

In the example of FIG. 14, a step difference occurs in the pixel value VAL between one pixel group GP and another, and thus the step difference in the pixel value VAL results in being more visible. Meanwhile, in the example of FIG. 15, the region W2 to be subject to the read operation of the readout circuit 20 is made wider by two light-receiving pixels P than the region of the pixel group GP, thus allowing two regions W2 corresponding to adjacent pixel groups GP to overlap each other by four light-receiving pixels P in an overlap region W3. In this overlap region W3, a step difference occurs in the pixel value VAL between one light-receiving pixel P and another. This enables the step difference in the pixel value VAL to be less visible.

Further, in the example of FIG. 16, the region W2 to be subject to the read operation of the readout circuit 20 is made wider by eight light-receiving pixels P than the region of the pixel group GP, thus allowing the two regions W2 corresponding to adjacent pixel groups GP to overlap each other by 16 light-receiving pixels P in the overlap region W3. In this overlap region W3, a step difference occurs in the pixel value VAL between one light-receiving pixel P and another. In the example of FIG. 16, a step difference occurs in the pixel value VAL between one light-receiving pixel P and another in the overlap region W3 wider than the example of FIG. 15, thus enabling the step difference in the pixel value VAL to be still less visible.

Next, description is given, by referring to several examples, of arrangement of the light-receiving pixels P5 that supply the signal SIG to the readout circuit 205 in the operation mode M2.

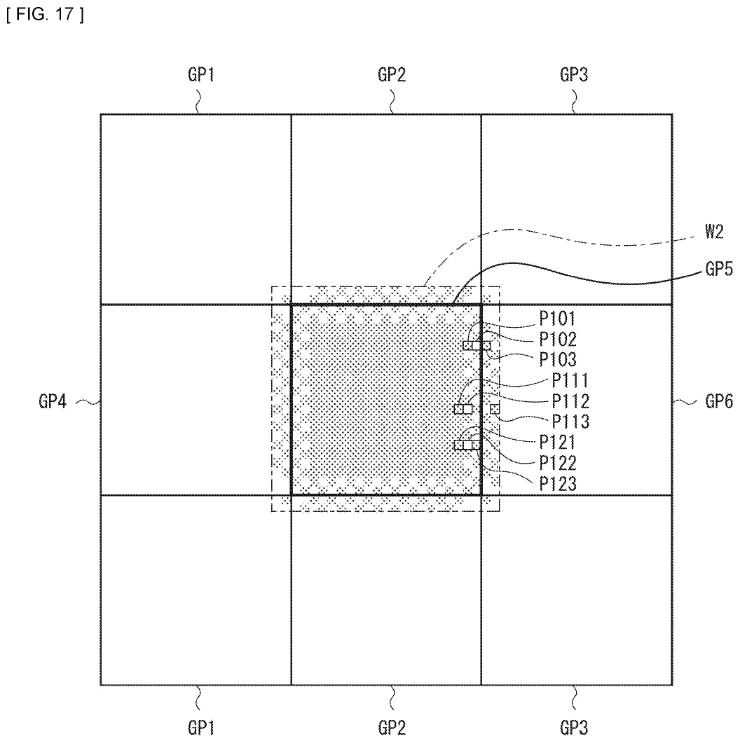

FIG. 17 illustrates an example of arrangement of the light-receiving pixels P5. In FIG. 17, a shaded part indicates that the light-receiving pixels P5 are arranged. In this example, the pixel group GP includes 441 (21×21) light-receiving pixels P. In addition, the region W2 to be subject to the read operation of the readout circuit 205 is made wider by two light-receiving pixels P than the region of the pixel group GP5. In this example, the light-receiving pixels P5 are arranged in a checkerboard pattern near the boundary between the pixel groups GP.

Here, attention is focused on three light-receiving pixels P5 arranged in a lateral direction. For example, light-receiving pixels P101, P102, and P103 are arranged in this order in the lateral direction. The light-receiving pixels P101 and P102 are arranged in the region of the pixel group GP5, and the light-receiving pixel P103 is arranged in a region of the pixel group GP6. The signals SIG generated by the light-receiving pixels P101 and P103 are subject to AD conversion by the AD converter 23 of the readout circuit 205 corresponding to the pixel group GP5, whereas the signal SIG generated by the light-receiving pixel P102 is subject to AD conversion by the AD converter 23 of a readout circuit 206 corresponding to the pixel group GP6.

In addition, for example, light-receiving pixels P111, P112, and P113 are arranged in this order in the lateral direction. The light-receiving pixels P111 and P112 are arranged in the region of the pixel group GP5, and the light-receiving pixel P113 is arranged in the region of the pixel group GP6. In this example, the light-receiving pixel P112 and the light-receiving pixel P113 are arranged apart from each other. The signals SIG generated by the light-receiving pixels P111 and P113 are subject to AD conversion by the AD converter 23 of the readout circuit 205 corresponding to the pixel group GP5, whereas the signal SIG generated by the light-receiving pixel P112 is subject to AD conversion by the AD converter 23 of the readout circuit 206 corresponding to the pixel group GP6.

In addition, for example, light-receiving pixels P121, P122, and P123 are arranged in this order in the lateral direction. The light-receiving pixels P121 to P123 are arranged in the region of the pixel group GP5. The signals SIG generated by the light-receiving pixels P121 and P123 are subject to AD conversion by the AD converter 23 of the readout circuit 205 corresponding to the pixel group GP5, whereas the signal SIG generated by the light-receiving pixel P122 is subject to AD conversion by the AD converter 23 of the readout circuit 206 corresponding to the pixel group GP6.

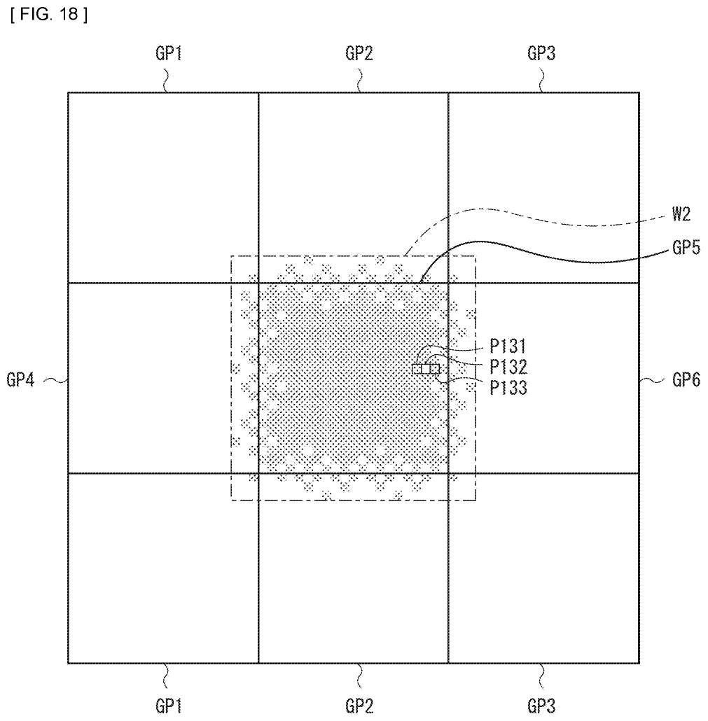

FIG. 18 illustrates another example of the arrangement of the light-receiving pixels P5. In this example, the region W2 to be subject to the read operation of the readout circuit 205 is made wider by three light-receiving pixels P than the region of the pixel group GP5. In this example, the light-receiving pixels P5 are arranged to allow the arrangement density of the light-receiving pixels P5 to be lower, as being closer to the outside of the region W2.

For example, light-receiving pixels P131, P132, and P133 are arranged in this order in the lateral direction. The light-receiving pixels P131 to P133 are arranged in the region of the pixel group GP5. The signals SIG generated by the light-receiving pixels P131 and P133 are subject to AD conversion by the AD converter 23 of the readout circuit 205 corresponding to the pixel group GP5, whereas the signal SIG generated by the light-receiving pixel P132 is subject to AD conversion by the AD converter 23 of the readout circuit 206 corresponding to the pixel group GP6.

In the examples of FIGS. 17 and 18, attention is focused on the three light-receiving pixels P5 arranged in the lateral direction, but the same applies also to three light-receiving pixels arranged in a longitudinal direction.

In this manner, in the operation mode M2, the regions W2 overlap each other in the adjacent pixel groups GP, thus enabling a step difference in the pixel value VAL to be less visible in the region W2. The operation mode M2 may be used in the ROI operation, or may be used in all screen imaging operations.

For example, more natural images can be obtained by using the operation mode M2 in all screen imaging operations.

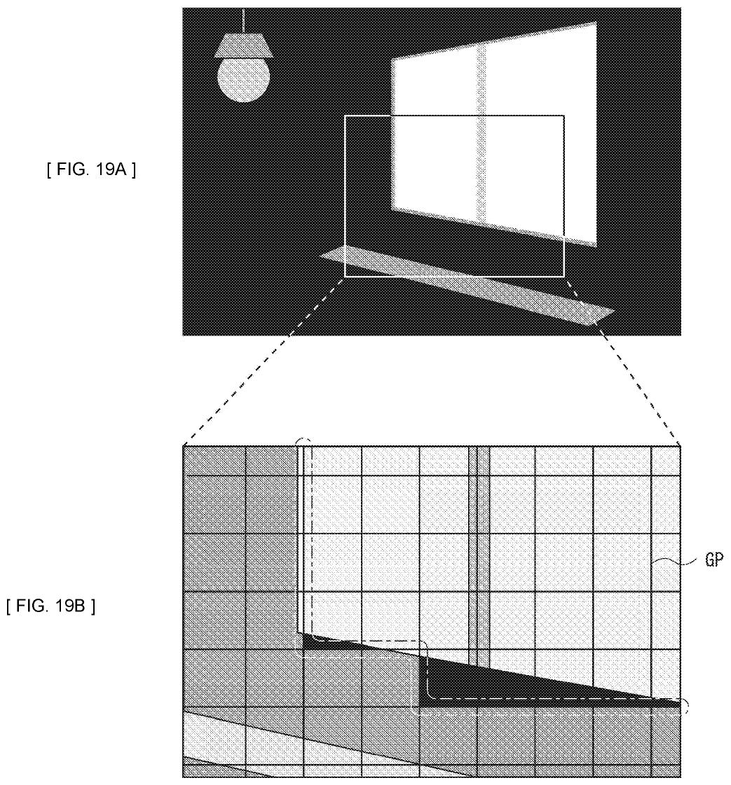

FIG. 19 illustrates an example of imaging, in which (A) illustrates a subject and (B) illustrates an imaging result of a portion surrounded by a frame of the subject illustrated in (A). A ruled line in (B) of FIG. 19 indicates a boundary between the pixel groups GP.

As illustrated in (A) of FIG. 19, an image of the subject may include both a bright portion and a dark portion in some cases. In this example, the outside of a window is bright and the inside of a room is dark. In such a case, for example, each of the plurality of AD converters 23 is able to set a gain depending on the brightness in the imaging apparatus 1. For example, the AD converter 23 that processes images in the bright portion sets the gain to be lower, whereas the AD converter 23 that processes images of the dark portion sets the gain to be higher. This enables the imaging apparatus 1 to prevent a so-called overexposed highlight or underexposed blocked up shadow, for example.

In this case, the gain is set, with the region corresponding to the pixel group GP as a unit, and thus there is a possibility that an image may be unnatural at a boundary (e.g., a portion surrounded by a broken line) between a region with a lower gain and a region with a higher gain, as illustrated in (B) of FIG. 19. In such a case, in the imaging apparatus 1, for example, the use of the operation mode M2 enables the step difference in the pixel value VAL caused by the difference in the gains in the plurality of AD converters 23 to be less conspicuous. This enables the imaging apparatus 1 to obtain a more natural image.

In this manner, the imaging apparatus 1 includes the pixel array 11 in which a first light-receiving element, a second light-receiving element, and a third light-receiving element are arranged in this order, and the readout section 13 including a first AD converter that performs AD conversion on the basis of each of the signal SIG generated by a first light-receiving pixel and the signal SIG generated by a third light-receiving pixel and a second AD converter that performs AD conversion on the basis of the signal SIG generated by a second light-receiving pixel. This enables, in the imaging apparatus 1, the step difference in the pixel value VAL to be still less visible, for example, in a case where there is a characteristic difference between the plurality of AD converters 23 or in a case where there is a quantization error therebetween. As a result, it is possible, in the imaging apparatus 1, to enhance image quality.

### [Effects]

As described above, in the present embodiment, there are provided the pixel array in which the first light-receiving element, the second light-receiving element, and the third light-receiving element are arranged in this order, and the readout section including the first AD converter that performs AD conversion on the basis of each of the signal generated by the first light-receiving pixel and the signal generated by the third light-receiving pixel and the second AD converter that performs AD conversion on the basis of the signal generated by the second light-receiving pixel, thus making it possible to enhance the image quality.

### 2. Usage Example of Imaging Apparatus

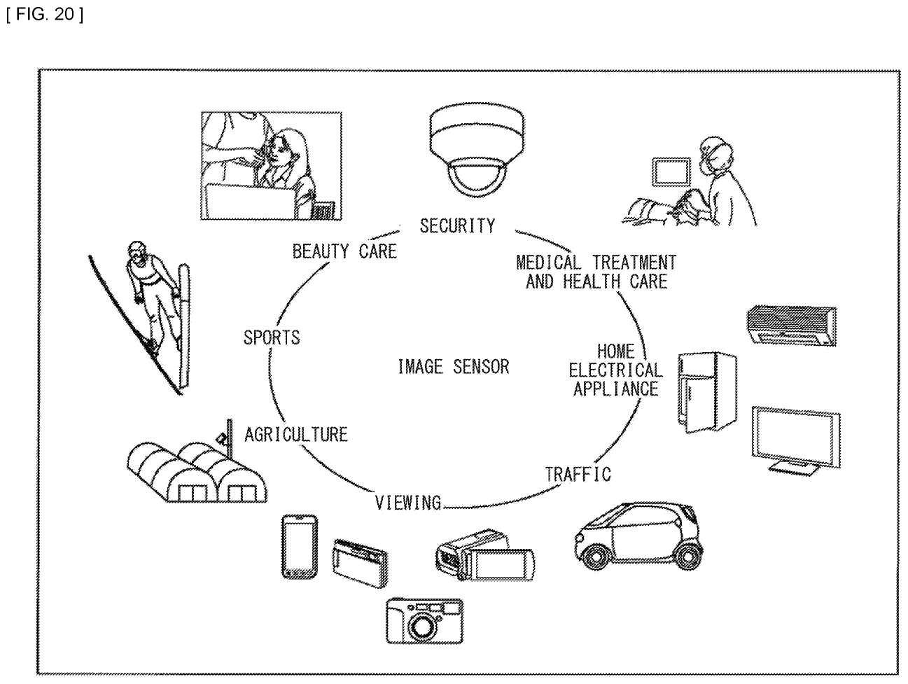

FIG. 20 illustrates a usage example of the imaging apparatus 1 according to the foregoing embodiment. For example, the imaging apparatus 1 described above is usable in a variety of cases of sensing light, including visible light, infrared light, ultraviolet light, and X-rays as follows.
Apparatuses that shoot images for viewing, including digital cameras and mobile equipment having a camera function
Apparatuses for traffic use, including onboard sensors that shoot images of the front, back, surroundings, inside, and so on of an automobile for safe driving such as automatic stop and for recognition of a driver's state, monitoring cameras that monitor traveling vehicles and roads, and distance measuring sensors that measure distances including a vehicle-to-vehicle distance
Apparatuses for use in home electrical appliances including televisions, refrigerators, and air-conditioners to shoot images of a user's gesture and bring the appliances into operation in accordance with the gesture
Apparatuses for medical treatment and health care use, including endoscopes and apparatuses that shoot images of blood vessels by receiving infrared light
Apparatuses for security use, including monitoring cameras for crime prevention and cameras for individual authentication
Apparatuses for beauty care use, including skin measuring apparatuses that shoot images of skin and microscopes that shoot images of scalp
Apparatuses for sports use, including action cameras and wearable cameras for sports applications and the like
Apparatuses for agricultural use, including cameras for monitoring the states of fields and crops

### 3. Example of Application to Mobile Body

The technology (the present technology) according to the present disclosure is applicable to a variety of products. For example, the technology according to the present disclosure may be achieved as an apparatus to be installed aboard any type of mobile body such as an automobile, an electric vehicle, a hybrid electric vehicle, a motorcycle, a bicycle, a personal mobility, an airplane, a drone, a vessel, or a robot.

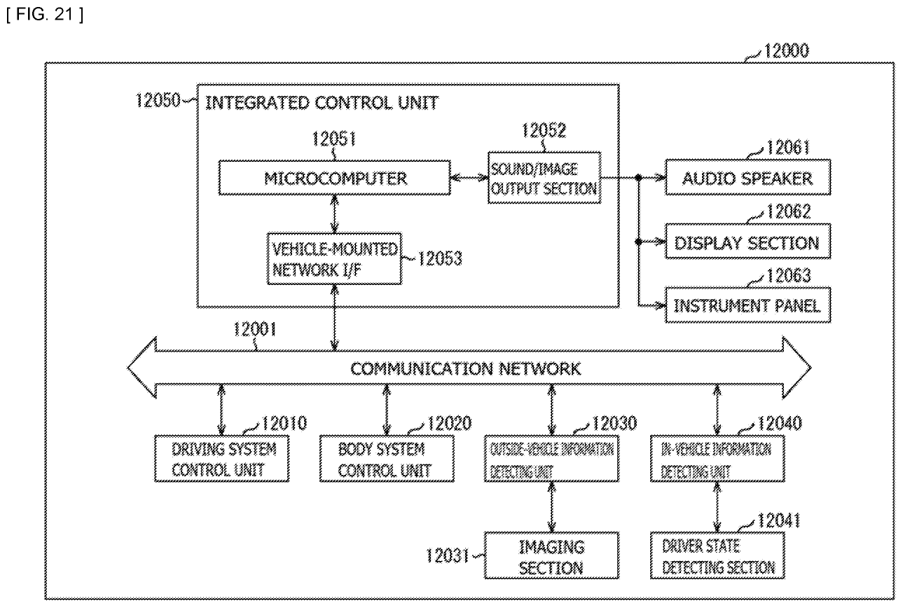

FIG. 21 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 21, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 21, an audio speaker 12061, a display section 12062, and an instrument panel 12063 are illustrated as the output device. The display section 12062 may, for example, include at least one of an on-board display and a head-up display.

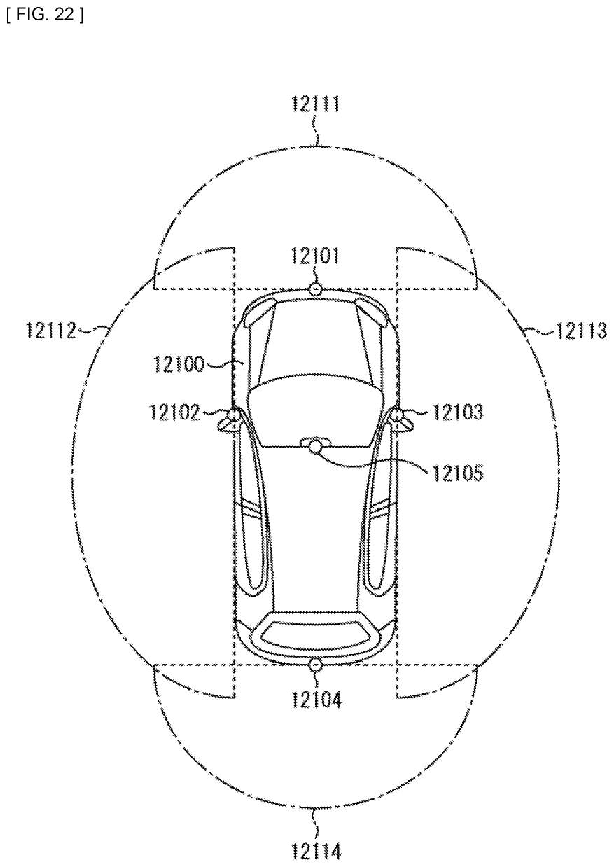

FIG. 22 is a diagram depicting an example of the installation position of the imaging section 12031.

In FIG. 22, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 22 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure is applicable has been described above. The technology according to the present disclosure is applicable to the imaging section 12031 among the above-described components. The imaging apparatus to be installed aboard a vehicle makes it possible to increase the image quality of a captured image. As a result, it is possible for the vehicle control system 12000 to achieve, with high accuracy, a collision avoidance or collision mitigation function for the vehicle, a following driving function based on vehicle-to-vehicle distance, a vehicle speed maintaining driving function, a warning function against collision of the vehicle, a warning function against deviation of the vehicle from a lane, and the like.

Although the present technology has been described above with reference to the embodiment and the specific practical application example thereof, the present technology is not limited to the embodiment and the like, and may be modified in a wide variety of ways.

For example, in the foregoing embodiment, the number of the light-receiving pixels P in the longitudinal direction and the number of the light-receiving pixels P in the lateral direction in the pixel group GP are the same as each other, but this is not limitative; they may be different from each other.

For example, the example of the arrangement of the light-receiving pixels P5 is not limited to the examples in FIGS. 17 and 18, and various arrangements can be employed.

It is to be noted that the effects described in the present specification are merely exemplary and non-limiting, and other effects may also be achieved.

It is to be noted that the present technology may have the following configurations. The present technology of the following configurations makes it possible to enhance the image quality.
(1)

An imaging apparatus including:
a pixel array including a plurality of light-receiving pixels including a first light-receiving pixel, a second light-receiving pixel, and a third light-receiving pixel, each generating a pixel signal in response to a received light amount, in which the first light-receiving pixel, the second light-receiving pixel, and the third light-receiving pixel are arranged in this order in a first direction; and
a readout section including a first AD converter that performs AD conversion on a basis of each of the pixel signal generated by the first light-receiving pixel and the pixel signal generated by the third light-receiving pixel, and a second AD converter that performs AD conversion on a basis of the pixel signal generated by the second light-receiving pixel.
(2)

The imaging apparatus according to (1), in which
the plurality of light-receiving pixels includes a fourth light-receiving pixel, a fifth light-receiving pixel, and a sixth light-receiving pixel,
the fourth light-receiving pixel, the fifth light-receiving pixel, and the sixth light-receiving pixel are arranged in this order in a second direction,
the first AD converter performs AD conversion on a basis of each of the pixel signal generated by the fourth light-receiving pixel and the pixel signal generated by the sixth light-receiving pixel, and
the readout section includes a third AD converter that performs AD conversion on a basis of the pixel signal generated by the fifth light-receiving pixel.
(3)

The imaging apparatus according to (2), in which
an imaging region in the pixel array is divided into a plurality of regions including a first region, a second region, and a third region,
the first region and the second region are adjacent to each other in the first direction,
the first region and the third region are adjacent to each other in the second direction,
the first light-receiving pixel, the second light-receiving pixel, the fourth light-receiving pixel, and the fifth light-receiving pixel are provided in the first region,
the third light-receiving pixel is provided in the second region, and
the sixth light-receiving pixel is provided in the third region.
(4)

The imaging apparatus according to (3), in which
the pixel array is provided in a first semiconductor substrate,
the readout section is provided in a second semiconductor substrate attached to the first semiconductor substrate,
the first AD converter of the readout section is arranged in a region, of the second semiconductor substrate, corresponding to the first region of the first semiconductor substrate,
the second AD converter of the readout section is arranged in a region, of the second semiconductor substrate, corresponding to the second region of the first semiconductor substrate, and
the third AD converter of the readout section is arranged in a region, of the second semiconductor substrate, corresponding to the third region of the first semiconductor substrate.
(5)

The imaging apparatus according to (3) or (4), in which the second light-receiving pixel and the third light-receiving pixel are adjacent to each other in the first direction.
(6)

The imaging apparatus according to (3) or (4), in which the second light-receiving pixel and the third light-receiving pixel are arranged apart from each other in the first direction.
(7)

The imaging apparatus according to any one of (3) to (6), in which
the plurality of light-receiving pixels includes two or more light-receiving pixels arranged in the second region and generating the pixel signal to be subject to AD conversion by the first AD converter,
the two or more light-receiving pixels include the third light-receiving pixel, and
the two or more light-receiving pixels are arranged in a boundary region near a boundary between the first region and the second region, in a region of the second region.
(8)

The imaging apparatus according to (7), in which, in the region of the second region, a pixel density of the two or more light-receiving pixels at a location distant by a first distance from the boundary between the first region and the second region is lower than a pixel density of the two or more light-receiving pixels at a location distant from the boundary by a second distance which is shorter than the first distance.
(9)

The imaging apparatus according to any one of (3) to (8), in which
the imaging apparatus has a first operation mode and a second operation mode,
in the first operation mode, the first AD converter performs AD conversion on a basis of each of the pixel signal generated by the first light-receiving pixel and the pixel signal generated by the second light-receiving pixel, and the second AD converter performs AD conversion on a basis of the pixel signal generated by the third light-receiving pixel, and
in the second operation mode, the first AD converter performs AD conversion on a basis of each of the pixel signal generated by the first light-receiving pixel and the pixel signal generated by the third light-receiving pixel, and the second AD converter performs AD conversion on a basis of the pixel signal generated by the second light-receiving pixel.
(10)

The imaging apparatus according to (2), in which
an imaging region in the pixel array is divided into a plurality of regions including a first region, and
the first light-receiving pixel, the second light-receiving pixel, the third light-receiving pixel, the fourth light-receiving pixel, the fifth light-receiving pixel, and the sixth light-receiving pixel are provided in the first region.
(11)

The imaging apparatus according to (10), in which
the pixel array is provided in a first semiconductor substrate,
the readout section is provided in a second semiconductor substrate attached to the first semiconductor substrate, and
the first AD converter of the readout section is arranged in a region, of the second semiconductor substrate, corresponding to the first region of the first semiconductor substrate.

This application claims the priority on the basis of Japanese Patent Application No. 2021-009618 filed with the Japan Patent Office on Jan. 25, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. An imaging apparatus comprising:
a pixel array including a plurality of light-receiving pixels including a first light-receiving pixel, a second light-receiving pixel, and a third light-receiving pixel, each generating a pixel signal in response to a received light amount, in which the first light-receiving pixel, the second light-receiving pixel, and the third light-receiving pixel are arranged in this order in a first direction; and
a readout section including a first AD converter that performs AD conversion on a basis of each of the pixel signal generated by the first light-receiving pixel and the pixel signal generated by the third light-receiving pixel, and a second AD converter that performs AD conversion on a basis of the pixel signal generated by the second light-receiving pixel.

2. The imaging apparatus according to claim 1, wherein
the plurality of light-receiving pixels includes a fourth light-receiving pixel, a fifth light-receiving pixel, and a sixth light-receiving pixel,
the fourth light-receiving pixel, the fifth light-receiving pixel, and the sixth light-receiving pixel are arranged in this order in a second direction,
the first AD converter performs AD conversion on a basis of each of the pixel signal generated by the fourth light-receiving pixel and the pixel signal generated by the sixth light-receiving pixel, and
the readout section includes a third AD converter that performs AD conversion on a basis of the pixel signal generated by the fifth light-receiving pixel.

3. The imaging apparatus according to claim 2, wherein
an imaging region in the pixel array is divided into a plurality of regions including a first region, a second region, and a third region,
the first region and the second region are adjacent to each other in the first direction,
the first region and the third region are adjacent to each other in the second direction,
the first light-receiving pixel, the second light-receiving pixel, the fourth light-receiving pixel, and the fifth light-receiving pixel are provided in the first region,
the third light-receiving pixel is provided in the second region, and
the sixth light-receiving pixel is provided in the third region.

4. The imaging apparatus according to claim 3, wherein
the pixel array is provided in a first semiconductor substrate,
the readout section is provided in a second semiconductor substrate attached to the first semiconductor substrate,
the first AD converter of the readout section is arranged in a region, of the second semiconductor substrate, corresponding to the first region of the first semiconductor substrate,
the second AD converter of the readout section is arranged in a region, of the second semiconductor substrate, corresponding to the second region of the first semiconductor substrate, and
the third AD converter of the readout section is arranged in a region, of the second semiconductor substrate, corresponding to the third region of the first semiconductor substrate.

5. The imaging apparatus according to claim 3, wherein the second light-receiving pixel and the third light-receiving pixel are adjacent to each other in the first direction.

6. The imaging apparatus according to claim 3, wherein the second light-receiving pixel and the third light-receiving pixel are arranged apart from each other in the first direction.

7. The imaging apparatus according to claim 3, wherein
the plurality of light-receiving pixels includes two or more light-receiving pixels arranged in the second region and generating the pixel signal to be subject to AD conversion by the first AD converter,
the two or more light-receiving pixels include the third light-receiving pixel, and
the two or more light-receiving pixels are arranged in a boundary region near a boundary between the first region and the second region, in a region of the second region.

8. The imaging apparatus according to claim 7, wherein, in the region of the second region, a pixel density of the two or more light-receiving pixels at a location distant by a first distance from the boundary between the first region and the second region is lower than a pixel density of the two or more light-receiving pixels at a location distant from the boundary by a second distance which is shorter than the first distance.

9. The imaging apparatus according to claim 3, wherein
the imaging apparatus has a first operation mode and a second operation mode,
in the first operation mode, the first AD converter performs AD conversion on a basis of each of the pixel signal generated by the first light-receiving pixel and the pixel signal generated by the second light-receiving pixel, and the second AD converter performs AD conversion on a basis of the pixel signal generated by the third light-receiving pixel, and
in the second operation mode, the first AD converter performs AD conversion on a basis of each of the pixel signal generated by the first light-receiving pixel and the pixel signal generated by the third light-receiving pixel, and the second AD converter performs AD conversion on a basis of the pixel signal generated by the second light-receiving pixel.

10. The imaging apparatus according to claim 2, wherein
an imaging region in the pixel array is divided into a plurality of regions including a first region, and
the first light-receiving pixel, the second light-receiving pixel, the third light-receiving pixel, the fourth light-receiving pixel, the fifth light-receiving pixel, and the sixth light-receiving pixel are provided in the first region.

11. The imaging apparatus according to claim 10, wherein
the pixel array is provided in a first semiconductor substrate,
the readout section is provided in a second semiconductor substrate attached to the first semiconductor substrate, and
the first AD converter of the readout section is arranged in a region, of the second semiconductor substrate, corresponding to the first region of the first semiconductor substrate.
